(19) United States
(12) Patent Application Publication
(10) Pub. No.: US 2011/0302533 A1
(43) Pub. Date: Dec. 8, 2011

(54) Operating Device for an Electric Domestic Appliance and Operating Method

(75) Inventors: Frank Stuhr, Kurnbach (DE); Carmelo Zarcone, Olbronn (DE)

(73) Assignee: E.G.O. ELEKTRO-GERÄTEBAU GMBH, Oberderdingen (DE)

(21) Appl. No.: 13/210,691

(22) Filed: Aug. 16, 2011

Related U.S. Application Data
(63) Continuation of application No. PCT/EP2010/052204, filed on Feb. 22, 2010.

(30) Foreign Application Priority Data
Feb. 23, 2009 (DE) 10 2009 011 678.8

(51) Int. Cl. G06F 3/048; H03K 17/98

(52) U.S. Cl. 715/825; 200/5 A

(57) ABSTRACT

An operating device for an electric domestic appliance has an operating panel with operating elements, wherein the operating elements are touch switches, which can be actuated by placing a finger on the operating panel or moving a finger over the operating panel. The operating device advantageously has a large touch screen. The operating panel has at least in the area of the operating elements a convexly curved surface contour, so that virtual rollers can be simulated by the display in the form of the touch screen and can be rotated by moving the finger over it. Selected functions are activated by touching them.

### RELATED APPLICATIONS

This application is a continuation of PCT/EP2010/052204, filed on Feb. 22, 2010, which in turns claims priority to DE 10 2009 011 678.8 filed on Feb. 23, 2009, the contents of both of which are incorporated by reference for all that each teaches.

### FIELD OF APPLICATION

The invention relates to an operating device for an electric domestic appliance, to an electric domestic appliance having such an operating device, and to an operating method that can be performed with such an operating device.

### BACKGROUND

Operating devices having touch switches as operating elements are known, for example, for hobs or washing machines. See, for example, DE 10133135 A1, which discloses that it is possible to run a finger over an elongated sensor strip having several touch switches in order to set a value, i.e., to operate it.

Furthermore, it is known, for example, from DE 102005051297 A1 how to provide mechanical rollers on an electric domestic appliance. By turning and setting of a certain rotary position, a value can be picked that is then selected/confirmed by a further operating step and adopted in a sequence program.

### SUMMARY

An object underlying the invention is to provide an operating device of the type mentioned at the outset, a corresponding electric domestic appliance and a corresponding operating method using the same wherein problems arising in the prior art can be solved and in particular an advantageous design and operation are made possible.

This problem is solved by an operating device, electric domestic appliance, and an operating method having the features as claimed herein. Advantageous and preferred embodiments of the invention form the subject matter of the further claims and are explained in greater detail in the following. Some of the subsequently listed features are explained only for the operating device, the electric domestic appliance or the operating method. They should, however, apply regardless for the operating device, for the electric domestic appliance, and for the operating method. The wording of the claims is made into part of the substance of the description by express reference.

It is provided that the operating elements of the operating device are touch switches, i.e., these are not mechanical operating elements that have to be moved or pressed in. Rather, these touch switches can be actuated by placing a finger on the operating panel of the operating device or moving a finger over it. In accordance with one aspect of the invention, the operating panel has at least in the area of the operating elements a convexly curved surface contour. Advantageously, the curved surface contour follows a stroking or movement direction predetermined for the operation by moving a finger over it.

This makes it possible to achieve operation or to permit an operating method which is performed with touch switches, i.e., not with mechanically operated elements, and providing the appearance of performing operating processes by turning or moving rollers. In particular, it permits an intuitive and rapid operation. Furthermore, several operating options or so-called menu items can be displayed/viewed at the same time. It is also possible to discern more readily the progress made during apparent rotation of the settable values by moving the finger over it more quickly or more slowly as a kind of progress indicator.

Capacitive-based touch switches are advantageously used as the operating elements and have appropriate capacitive sensor elements that are advantageously arranged underneath a surface forming the operating panel. In particular, touch switch is a surface of the electric domestic appliance or it forms a part of its housing. Touch switches of this type are designed for so-called sliders, for example in accordance with DE 10133135 A1 or DE 102005018298 A1, the entire contents of which is incorporated by express reference in the present specification.

The electrically conductive surface needed for such capacitive sensor elements can be provided in different ways, for example also in accordance with the two aforementioned documents of the prior art. They are advantageously designed in a translucent manner, which will be explained in more detail in the following, and can accordingly have a translucent and electrically conductive coating. To do so, ITO coatings, in particular, are ideal and can for example also be deposited or printed onto the rear of a cover for the operating panel made of transparent plastic.

As previously stated, a sensor element for a touch switch can be designed as a so-called slider with a longitudinal extent, as is also known in principle, for example from the two aforementioned documents of the prior art. The longitudinal extent can then advantageously run along the curvature and in the direction of the circumference of the curvature. It is particularly advantageous for several such sensor elements or sliders running parallel to one another to be provided. They can form several touch switches or simulate during operation several roller-like operating elements which seemingly rotate under finger contact.

In a further advantageous embodiment of the invention, display elements can be provided to indicate a working state and, in particular, an operating state and also to advantageously make the operating elements visible in the first place. To do so, the display elements are advantageously arranged close to the operating elements and can be covered by the latter in the same area, in particular when the operating elements or sensor elements of the touch switches in accordance with the above statements are designed transparently. To do so, it can be particularly advantageously provided that the display elements cover at least the same surface as the operating elements, and in particular are even larger. In this way, it is possible with such display elements to represent seemingly physically or mechanically operating elements such as advantageously the aforementioned rollers. Thus an operator sees not only where he has to place his finger on an operating element for a certain operating function, but also how to alter the operating function or setting to match this operating function. It is precisely when the operating elements simulate, by means of the display elements, the previously described rollers that the appropriate symbols or figures on the rollers can move underneath the operating panel to match the movement of a finger placed on it and moving over it as though they were real mechanical rollers.

Display elements advantageously have or form a large-surface and flexible display. This display is arranged underneath the operating panel, preferably in accordance with the above description, directly underneath the operating elements or their sensor elements. The display should likewise be curved to match the curvature of the operating panel for a clear and convincing representation and also for easier installation. It is particularly preferable for the display to be a full graphic display which can show not only just figures or symbols such as a standard 7-segment display, but also show or simulate the previously described movement of rollers. On the one hand it is possible, when several of the previously described sliders are present which each advantageously simulate a roller, to provide a separate display for each of these sliders. An even better and more convincing graphic effect is obtained when a single large display is provided for the entire operating device or on the entire operating panel. It can then for example also be provided that the rollers can seemingly not only be rotated about their rotary axis by moving a finger over them, but also moved laterally. By a virtual lateral movement of this type, it is for example possible in accordance with an embodiment of the inventive operating method to perform a selection operation or a confirmation operation.

To create a sufficiently large operating panel with sufficient length for a finger to run over it on the operating element, it can be provided that a convex curvature of the operating panel describes a pitch circle with an angle of arc of at least 60°. Such an angle of about 90° is particularly advantageous, so that an operating panel so curved can be integrated very readily into a front edge of an inventive electric domestic appliance between its vertical front face and its horizontal top. Alternatively, it can be a raised area at the rear of the appliance.

In another embodiment of the invention, the curvature runs evenly over the width of the operating device. This facilitates its manufacture, in particular with a large-surface display element provided underneath.

In another embodiment of the invention, the operating device takes up only a part of the width or front edge of an electric domestic appliance provided with it. This can for example be a quarter or a half, in some circumstances even slightly more. In another advantageous embodiment of the invention, the operating device can be designed such that it takes up or forms the entire corresponding edge or front edge of the electric domestic appliance. This provides sufficient space for a large-surface operating device which can be easily read off and operated. Above all, it is also possible in this way to provide an attractive and consistent design of the electric domestic appliance. A drawer or other loading facility for washing powder in a washing machine can then still be integrated into the front edge.

These and further features can be gathered not only from the claims, but also from the description and drawings, wherein the individual features, both singly or severally in the form of subcombinations, can be implemented in an embodiment of the invention and in other fields and can represent advantageous and independently protectable designs for which protection is claimed here. The subdivision of the application into individual sections and the subheadings in no way restrict the general validity of the statements made thereunder.

### BRIEF DESCRIPTION OF THE DRAWINGS

Embodiments of the invention are shown schematically in the drawings and are explained in detail in the following drawings, wherein:

FIG. 1 illustrates an oblique view from the front and side onto a front face or front edge of an inventive electric domestic appliance in the form of a washing machine with rounded front edge together with an operating device thereon,

FIG. 2 illustrates a representation of the electric domestic appliance from FIG. 1 from a slightly different perspective illustrating the operating method, where the operating device represents several roller-like operating elements,

FIG. 3 illustrates a representation similar to FIG. 2 with displayed menu items on the operating device and a hand of an operator, and

FIG. 4 illustrates a representation of FIG. 3 from a slightly different angle.

### DETAILED DESCRIPTION

The figures show an electric domestic appliance 11 which in the present embodiment is a washing machine The washing machine has in the area of the transition between a front face 12 and a top 13, i.e., practically on the upper front edge, an operating device 15 with an operating panel 17. This operating device here takes up almost the entire width of the electric domestic appliance 11, which is however not essential. The operating panel 17 is advantageously designed as a continuous and curved cover of at least largely transparent plastic. Underneath the operating panel 17, operating elements are provided (not shown) with touch switches or capacitive sensor elements. Even though they are not explicitly shown, they can however be designed, for example, in accordance with DE 10133135 A1 or DE 102005018298 A1 as mentioned in the above and to which explicit incorporation by reference is made with respect to the design. If an operating panel 17 is designed in transparent plastic, it is then possible to apply or print on its rear face a capacitive and flat sensor element made of an ITO coating. To that extent, this design is within the skills of an ordinary a person skilled in the art and it requires no further explanation here.

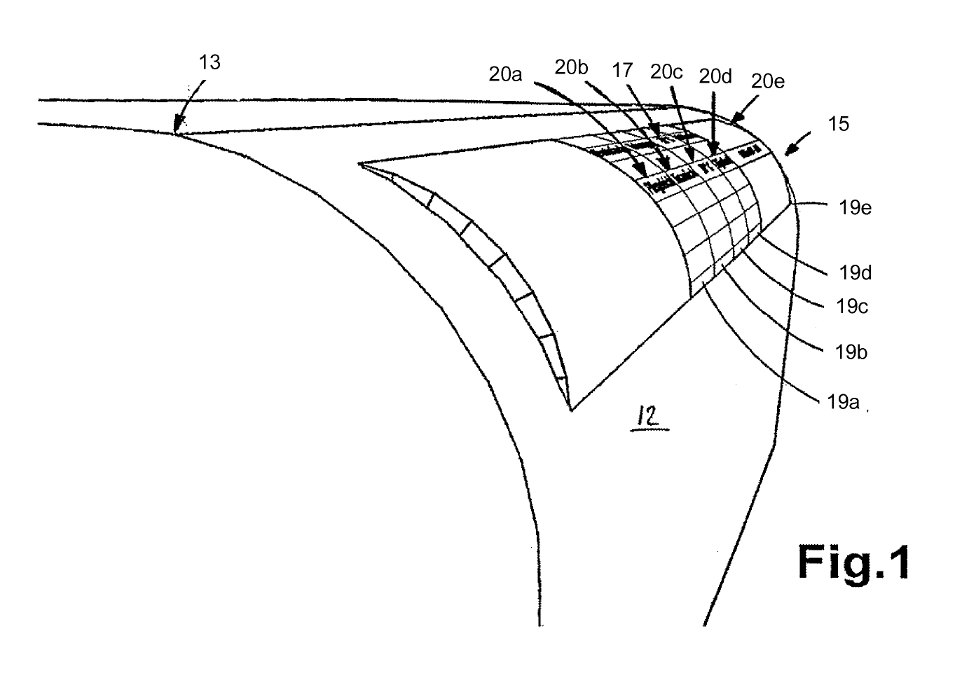

It can be discerned from FIG. 1 that the operating panel 17 has five elongated and strip-like operating elements 19a to 19e (collectively referred to as elements 19) which follow with a similar width the curvature of the operating element 17 and extend over almost its entire curvature. As a result, the operating elements 19a-19e are also curved in their longitudinal direction.

Underneath each operating element 19 is a display 20a to 20e (collectively referred to as displays 20). These displays 20 advantageously take up at least the same area as the operating elements 19, and advantageously are slightly larger, in particular wider. It is preferably possible that the displays are combined or that several displays are formed by one display unit. The displays 20a to 20d in particular can be advantageously formed by a single display unit or are areas thereof, the single display unit having an appropriate extent underneath the operating panel 17.

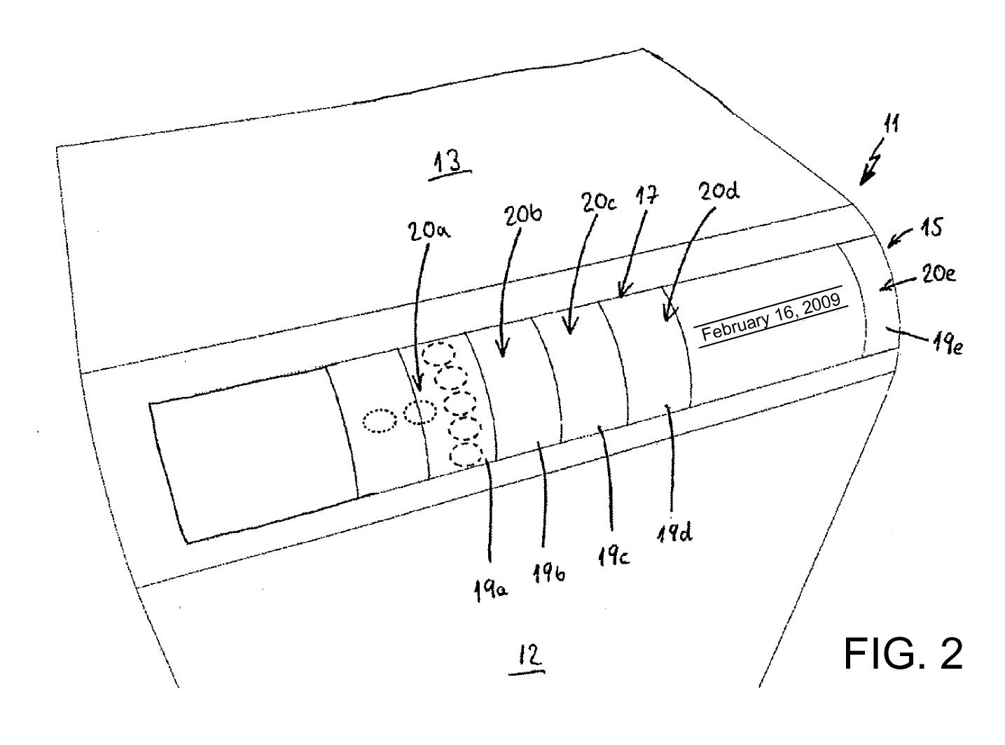

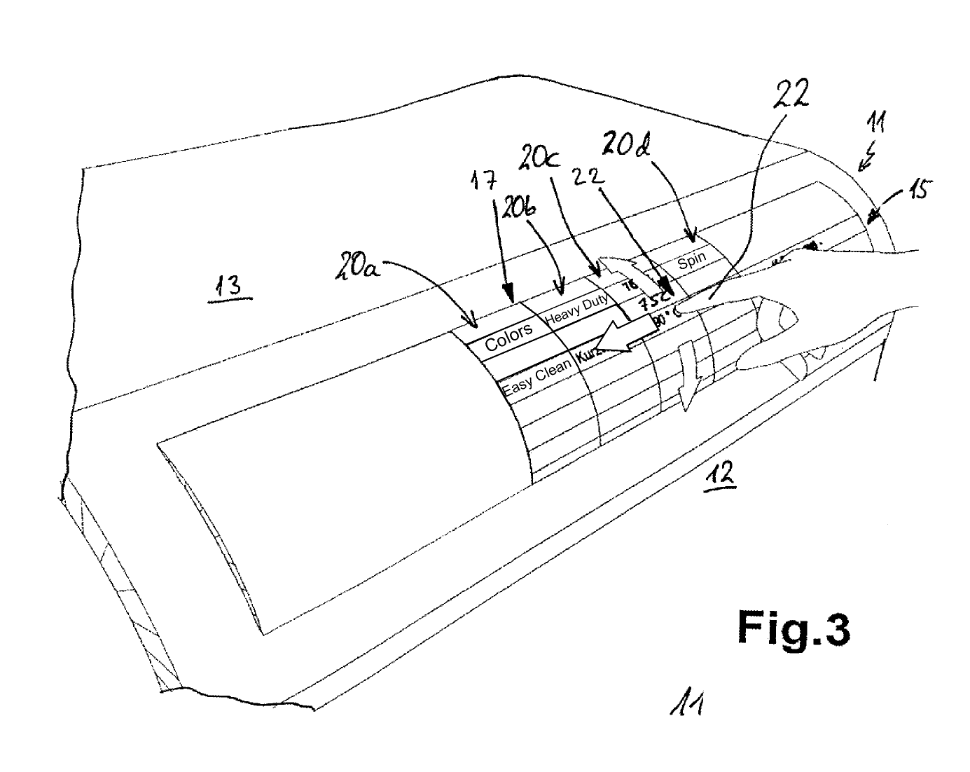

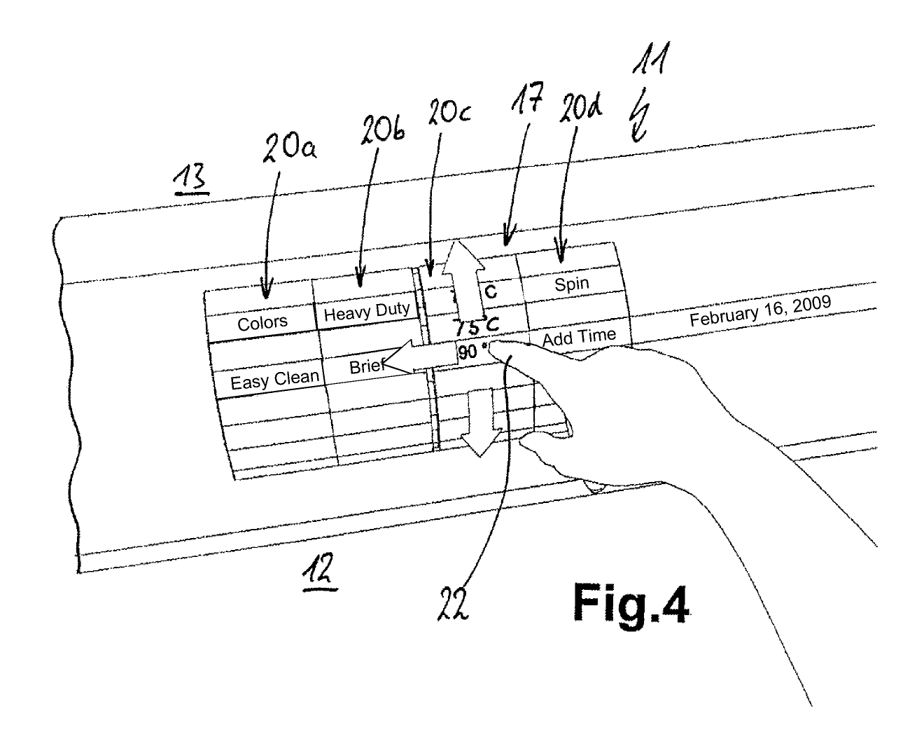

Substantially, this creates with the operating panel 17 a type of curved touch screen. As indicated by FIG. 3 and FIG. 4, the operating device 15 can detect a touch or tap of a finger 22 on one of the operating elements 19 as indicated by the small arrow. Above all, however, it is also possible for the operating device 15 to detect when the finger 22 as shown by the larger arrow moves, following the radius of the curvature, upwards or downwards. The displays 20 can then move various menu items upwards or downwards, for example in FIG. 3 extreme left the illustrated menu item “Colors” and others such as “Easy Clean” and many more as shown by the movement of the finger 22. These different terms or menu items are shown in FIG. 2 by the dashed-line circles on the left-hand operating element 19a with the display 20a. The representation on the display 20a, or also for example on the top of the operating panel 17, shows that a menu item located at a certain position along the radius of the curvature is considered activated or preselected. In FIG. 2, this can be advantageously the middle of the menu items indicated by the dashed-line circles, and it can then be selected by touching it with the finger 22, i.e., after a roller-like upward or downward rotation or movement.

Alternatively to simply touching it, after the further menu items have then been set at the operating element 19c using the display 20c directly adjacent to it on the right, it is possible by leftward movement of the finger 22 in accordance with the dotted-line representation of the circle to draw the roller indicated by the display 20c with the menu item slightly to the left into an area which is also taken up by the display, i.e., right up to the roller of the display 20b. This is shown by FIG. 4. The display then shows this roller precisely in this displaced setting and hence makes clear that it is precisely this menu item, in this case a temperature of 90° C., that has been selected.

This selection and confirmation method can be performed for all four menu items as per the operating elements 19a to 19d at the displays 20a to 20d. It is then possible to start the electric domestic appliance either using a separate operating element or using the operating element 19e. Alternatively, a timer can be set for a delayed start of operation at this operating element 19e, likewise again using a previously described roller operation.

Based on the five menu items shown in dashed lines on the display 20a in FIG. 2, it can be readily envisioned, despite the simplified representation, how these menu items are rotated downwards by moving a finger 22 over them matching the arrow in the representation/of the display 20a. This rotation is performed such that the visual impression is given that the finger 22 is actually moving a mechanical roller. It can therefore also be moved in a manner adjusted to the speed of the finger 22, possibly also with appropriate trailing or overshooting.

An advantage of such a roller representation and roller operation shown only by a display and in a virtual or simulated form is that an operator can largely determine himself within broad limits the speed at which the various menu items on a display 20 are gone through. If the finger 22 is moved slowly, the displayed virtual roller also moves very slowly and the various menu items or options appear in a very slow sequence. If the finger 22 is moved much faster, because the operator knows for example that the required menu item is still quite a long way away, he can reach this menu item considerably faster.

The further advantage of the virtual rollers lies not only in the closed and hence attractive and easy-to-clean surface of the operating device 15, but also in the fact that the virtual rollers can be moved leftwards or rightwards, for example to make the selection. They can also, if in the case of a certain predetermined program sequence a menu item group associated with a roller and hence with an operating element 19 or with the display 20 is not even provided, omit the latter from the representation or only show it faintly. The possibilities for displaying information are therefore considerably expanded.

1. An operating device for an electric domestic appliance comprising,
an operating panel with operating elements,
wherein said operating elements are touch switches, said touch switches are configured to be actuated by placing a finger on said operating panel or moving said finger over it, and
wherein said operating panel has at least in an area of said operating elements a convexly curved surface contour.

2. The operating device according to claim 1, wherein said operating elements are capacitive based touch switches with sensor elements arranged underneath a surface forming said operating panel.

3. The operating device according to claim 1, wherein said sensor elements are configured sliders with a longitudinal extent along said curvature.

4. The operating device according to claim 3, comprising a plurality of sensor elements configured as said sliders provided in parallel and at a distance from one another.

5. The operating device according to claim 1, wherein said sensor elements for said operating elements have a translucent and electrically conductive coating.

6. The operating device according to claim 1, wherein said surface forming said operating panel comprises translucent plastic or glass.

7. The operating device according to claim 1, wherein display elements are provided adjacent to said operating elements.

8. The operating device according to claim 1, wherein display elements are provided at least partially covering said operating elements in a same area.

9. The operating device according to claim 8, wherein the display elements cover at least a same area as said operating elements.

10. The operating device according to claim 8, wherein said display elements have or form a large-surface and flexible display, said display being arranged underneath said operating panel.

11. The operating device according to claim 1, wherein a convex curvature of said operating panel describes a pitch circle of at least 60° in extent.

12. The operating device according to claim 11, wherein a radius of said convex curvature is between 2 cm and 10 cm.

13. The operating device according to claim 1, wherein said convex curvature of said operating panel has a longitudinal extent with constant curvature.

14. The operating device according to claim 13, wherein said longitudinal extent of said operating panel is over a width of said operating device.

15. An electric domestic appliance comprising:
an operating device comprising
an operating panel and
operating elements,
wherein said operating elements are touch switches configured to be actuated by placing a finger on said operating panel or moving said finger over said operating panel,
wherein said operating panel has at least in an area of said operating elements a convexly curved surface contour, and
wherein said operating device is provided on an edge of said electric domestic appliance.

16. The electric domestic appliance according to claim 15, wherein said operating device is provided on a top front edge.

17. The electric domestic appliance according to claim 15, wherein said operating device extends along an entire front edge of said electric domestic appliance.

18. The electric domestic appliance according to claim 17, wherein said operating device has a constant curvature.

19. An operating method for an appliance comprising an operating device wherein said operating device has an operating panel with operating elements,
wherein said operating elements are touch switches, said touch switches are configured to be actuated by placing a finger on said operating panel or moving said finger over it,
wherein said operating panel has at least in an area of said operating elements a convexly curved surface contour, and
wherein said operating device is provided on an edge of said electric domestic appliance, said operating method comprising:
placing and moving said finger over one of said operating element; and
in response there to, triggering an operating function or changing a selection item or menu item from a sequence program.

20. The operating method according to claim 19, wherein by placing and moving said finger over one said operating element on said operating panel in a direction vertical to the longitudinal extent of said operating panel, several said menu items or said selection items are successively changingly or alternatingly displayed.

21. The operating method according to claim 20, wherein one said menu item or one said selection item displayed at an unchanging position is selectable by touching it again using said finger.

22. The operating method according to claim 21, wherein said unchanging position is approximately at a middle of a level of said operating panel.

23. The operating method according to claim 19, wherein by placing a finger on one said operating element on said operating panel and moving it in a longitudinal direction of said operating panel, a roller-like operating element shown by a display is shown moved leftwards.

24. The operating method according to claim 21, wherein by placing a finger on one said operating element on said operating panel and moving it in a longitudinal direction of said operating panel, one said menu item or one said selection item displayed at a position according to claim 21 is considered as selected or set respectively.
